(19) United States
(12) Patent Application Publication
(10) Pub. No.: US 2025/0244702 A1
(43) Pub. Date: Jul. 31, 2025

(54) METHOD FOR CONTROLLING MULTIPLE POWER SUPPLIES IN AN IMAGE FORMING APPARATUS

(71) Applicant: CANON KABUSHIKI KAISHA, Tokyo (JP)

(72) Inventors: MASATAKA MOCHIZUKI, Shizuoka (JP); HOSU YEU, Shizuoka (JP)

(21) Appl. No.: 19/038,889

(22) Filed: Jan. 28, 2025

(30) Foreign Application Priority Data
Jan. 29, 2024 (JP) 2024-011257

(51) Int. Cl. G03G 15/00; G01R 19/00

(52) U.S. Cl. CPC G03G 15/5004; G01R 19/0092; G03G 15/80

(57) ABSTRACT

A controller operates a first power supply and a second power supply in a current detection period in which a detection circuit detects a charging current, thereby applying a superimposed voltage generated by superimposing a voltage of a first polarity and a voltage of a second polarity to a transfer member. The controller determines a surface potential of an image bearing member based on the charging current detected in the current detection period.

### BACKGROUND OF THE INVENTION

### Field of the Invention

The present invention relates to a method for controlling multiple power supplies in an image forming apparatus.

### Description of the Related Art

An image forming apparatus utilizing electrophotographic technologies requires a plurality of power supply circuits to generate a variety of high voltages (e.g., charging bias, developing bias, transfer bias, cleaning bias, etc.). The transfer bias (positive transfer bias) is a voltage of the positive polarity applied to a transfer roller to promote transfer of a toner image. The cleaning bias is a voltage of the negative polarity (negative transfer bias) for reversely transferring toner adhering to the transfer roller to a photosensitive drum. Therefore, there is a need for a power supply circuit that generates a positive transfer bias and another power supply circuit that generates a negative transfer bias. According to Japanese Patent Laid-Open No. 2007-206414, it has been proposed to share a power supply circuit for generating a negative charging bias as a power supply circuit for generating a cleaning bias.

Incidentally, it is necessary to accurately determine a surface potential of the photosensitive drum (e.g., a charging potential such as a dark portion potential and a bright portion potential) in order to accurately control a density of the toner image transferred to a sheet and suppress fogging of the toner. In Japanese Patent Laid-Open No. 2007-206414, when a charging bias is applied to the charging roller, a negative transfer bias is also applied to the transfer roller. Therefore, discharge occurs between the charging roller and the photosensitive drum, while an electric discharge also occurs between the transfer roller and the photosensitive drum, and it is difficult to accurately determine the charging potential.

### SUMMARY OF THE INVENTION

The present disclosure provides an image forming apparatus comprising: an image bearing member; a motor configured to rotationally drive the image bearing member; a charging member configured to charge a surface of the image bearing member which is rotationally driven by the motor; a light source configured to irradiate the surface of the image bearing member with light to form an electrostatic latent image; a developing member configured to develop the electrostatic latent image using a toner charged to a first polarity to form a toner image; a transfer member configured to transfer the toner image from the image bearing member to a transfer material; a first power supply configured to generate a voltage of the first polarity, supply the voltage of the first polarity to the charging member as a charging bias, and supply the voltage of the first polarity to the transfer member; a second power supply configured to generate a voltage of a second polarity opposite the first polarity and supply the voltage of the second polarity to the transfer member; a detection circuit configured to detect a charging current flowing between the charging member and image bearing member; and a controller configured to control the first power supply and the second power supply to determine a surface potential of the image bearing member based on the charging current, wherein the controller is further configured to operate the first power supply and the second power supply in a current detection period in which the detection circuit detects the charging current, thereby applying a superimposed voltage generated by superimposing the voltage of the first polarity and the voltage of the second polarity to the transfer member, and to determine the surface potential of the image bearing member based on the charging current detected in the current detection period.

Further features of the present invention will become apparent from the following description of exemplary embodiments (with reference to the attached drawings).

### BRIEF DESCRIPTION OF THE DRAWINGS

FIG. 1 illustrates an image forming apparatus.

FIG. 2 illustrates a power supply apparatus.

FIG. 3 illustrates a power supply circuit.

FIG. 4 illustrates a method for detecting a charging current.

FIG. 5 illustrates a detection sequence of a comparative example.

FIG. 6 illustrates detection sequence of a first embodiment.

FIG. 7 is a flowchart illustrating a method for control of the first embodiment.

FIG. 8 illustrates a relationship between an environmental condition (water content) and a load resistance.

FIG. 9 illustrates a detection sequence of a second embodiment.

FIG. 10 is a flowchart illustrating a method for control of the second embodiment.

FIG. 11 illustrates a detection sequence of a third embodiment.

FIG. 12 is a flowchart showing a method for control of the third embodiment.

FIG. 13 illustrates a detection sequence of a fourth embodiment.

FIG. 14 is a flowchart showing a method for control of the fourth embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate.

Furthermore, in the attached drawings, the same reference numerals are given to the same or similar configurations, and redundant description thereof is omitted.

### 1. First Exemplary Embodiment

### 1-1. Image Forming Apparatus

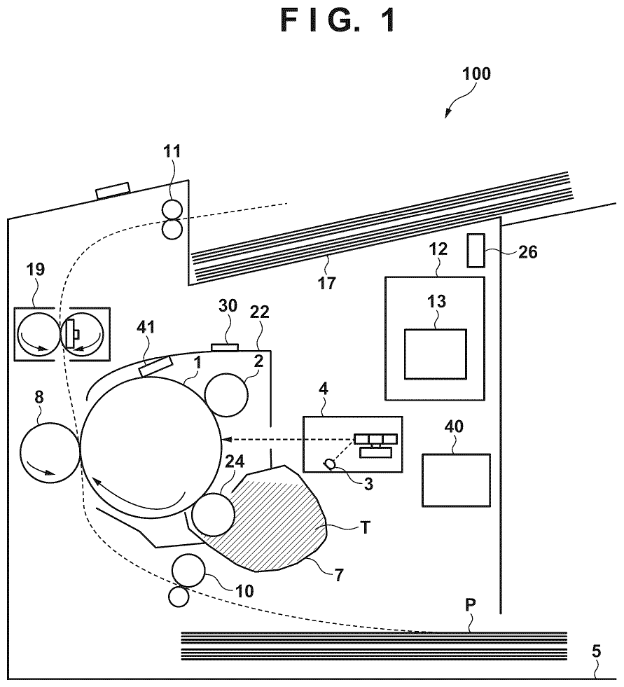

FIG. 1 shows an electrophotographic image forming apparatus 100. The image forming apparatus 100 is fitted with a removable process cartridge 22. The process cartridge 22 includes a photosensitive drum 1, a charging roller 2, a developing roller 24, a toner container 7, a cleaning member 41, and a non-volatile memory 30.

The engine controller 12 has a CPU 13. The CPU 13 is a processor that controls each unit of the image forming apparatus 100. The CPU 13 uses an environmental sensor 26 to detect a temperature and a humidity of an environment in which the image forming apparatus 100 is installed, and detects an amount of water content from the detected temperature and humidity.

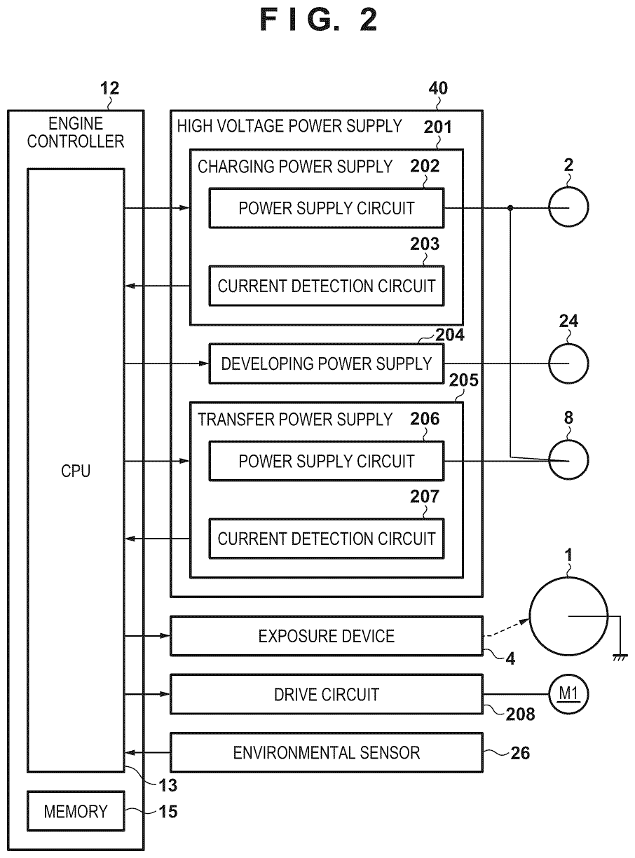

The photosensitive drum 1 is an image bearing member that is rotationally driven by a motor M1 shown in FIG. 2. The charging roller 2 is in contact with the photosensitive drum 1 and rotates following the photosensitive drum 1. The charging roller 2 receives a charging bias (e.g., a negative high voltage) from a high voltage power supply 40. As a result, an electric discharge occurs between the photosensitive drum 1 and the charging roller 2, and a discharging current (charging current) flows from the photosensitive drum 1 toward the charging roller 2. As a result, a surface of the photosensitive drum 1 is charged. The charging bias may be referred to as a charging voltage. A potential (surface potential) of a surface portion of surface portions of the photosensitive drum 1 that has passed through a charging nip formed between the photosensitive drum 1 and the charging roller 2 changes to a predetermined charging potential (dark portion potential VD) (charging process). A core metal of the photosensitive drum 1 is connected to a frame ground and is 0 [V]. A potential described below is the potential relative to the frame ground. An organic photosensitive layer made of resin is provided around the metal core.

As the photosensitive drum 1 rotates, the charged surface portion is irradiated with light output from a light source 3 of the exposure device 4. As a result, the surface potential of the exposed surface portion changes to the bright portion potential VL (exposure process). In addition, an electrostatic latent image corresponding to the image data is formed on the surface of the photosensitive drum 1 by exposure. The light source 3 may be a semiconductor laser or a light emitting diode such as an organic EL. EL is an abbreviation for electroluminescence.

As the photosensitive drum 1 rotates, the exposed surface portion arrives at the developing roller 24. The high voltage power supply 40 is a power supply apparatus that applies a developing bias to the developing roller 24. As a result, the toner T in the toner container 7 adheres to the surface of the photosensitive drum 1 through the developing roller 24, so that a toner image is formed (developing process).

As the photosensitive drum 1 rotates, the toner image is conveyed to the transfer nip. The transfer nip is formed between the transfer roller 8 and the photosensitive drum 1. The CPU 13 controls the high voltage power supply 40 to apply a positive transfer bias (e.g., a positive bias) to the transfer roller 8. As a result, the toner image carried on the surface of the photosensitive drum 1 is transferred to a sheet P (transfer process). The sheet P is stored in a sheet cassette 5, and is fed and conveyed by a feed roller 10.

The sheet P is conveyed to a fixing device 19. The fixing device 19 includes a cylindrical pressure roller and a hollow cylindrical heating film. The fixing device 19 applies heat and pressure to the sheet P and the toner image to fix the toner image on the sheet P (fixing process). A discharge roller 11 discharges the sheet P conveyed on the conveyance path onto a sheet tray 17.

Meanwhile, the toner T may remain on the surface of the photosensitive drum 1 without being transferred to the sheet P. When the transfer roller 8 is used for a long period of time, the surface of the transfer roller 8 may be contaminated with the toner T. When the transfer process is completed, the CPU 13 controls the high voltage power supply 40 to apply a cleaning bias (e.g., a high voltage of the negative polarity) to the transfer roller 8. As a result, the toner T erroneously adhering to the transfer roller 8 is re-transferred to the photosensitive drum 1. When the photosensitive drum 1 rotates, a surface portion to which the toner T adheres comes into contact with a cleaning member 41 called a cleaning blade. The cleaning member 41 scrapes and collects the toner T from the photosensitive drum 1.

As described above, the positive transfer bias for promoting transfer of the toner image and the negative transfer bias for cleaning the transfer roller 8 are alternately applied to the transfer roller 8. The high voltage power supply 40 requires a power supply circuit that generates the charging bias, a power supply circuit that generates the developing bias Vdc, a power supply circuit that generates the positive transfer bias, and a power supply circuit that generates the negative transfer bias. However, as will be described later, the high voltage power supply 40 can be made compact by using the power supply circuit that generates the charging bias also as the power supply circuit that generates the negative transfer bias. In this case, the negative transfer bias is output in conjunction with the charging bias. The transfer bias may be referred to as a transfer voltage.

The image density at the image forming apparatus 100 correlates with a development contrast Vcont. The development contrast Vcont is a potential difference between the bright portion potential VL of the photosensitive drum 1 and the developing bias Vdc. On the other hand, if the toner T adheres to an unexposed portion of the surface of the photosensitive drum 1, a white background portion of the sheet P may become dirty. This phenomenon is called toner fog. The toner fog correlates with the development back contrast Vback. That is, the toner fog is reduced by appropriately controlling the development back contrast Vback. The developing back contrast Vback is a potential difference between the dark portion potential VD of the photosensitive drum 1 and the developing bias Vdc.

As described above, the CPU 13 appropriately controls Vcont using the bright portion potential VL as a reference potential, and appropriately controls Vback using the dark portion potential VD as a reference potential. This means that the surface potential of the photosensitive drum 1 (dark portion potential VD and bright portion potential VL) needs to be obtained appropriately.

### 1-2. High Voltage Power Supply

### 1-2-1. Summary of High Voltage Power Supply

FIG. 2 shows the high voltage power supply 40. The high voltage power supply 40 includes a charging power supply circuit 201 that generates the charging bias and the negative transfer bias, a developing power supply circuit 204 that generates the developing bias, and a transfer power supply circuit 205 that generates the positive transfer bias. In the first embodiment, the charging bias and the negative transfer bias are generated as a shared bias.

That is, when the charging bias is output, the negative transfer bias is also output.

The charging power supply circuit 201 includes a power supply circuit 202 that generates a high voltage having the negative polarity based on an instruction from the CPU 13, and a current detection circuit 203 that detects a current (charging current) flowing through the charging roller 2 and reports the detected current to the CPU 13. The transfer power supply circuit 205 includes a power supply circuit 206 that generates a high voltage having the positive polarity based on an instruction from the CPU 13, and a current detection circuit 207 that detects a current (transfer current) flowing through the transfer roller 8 and reports the detected current to the CPU 13.

The CPU 13 drives the motor M1 through the drive circuit 208. The motor M1 rotationally drives a rotating member such as the photosensitive drum 1.

The exposure device 4 irradiates the surface of the photosensitive drum 1 with light based on an image signal supplied from the engine controller 12. The CPU 13 controls a fixing temperature of the fixing device 19 based on the amount of water content detected by the environmental sensor 26. In a second embodiment, the water content is used in yet another application. The CPU 13 executes a control program stored in a ROM area of a memory 15 and controls image forming apparatus 100 in accordance with the control program. ROM is an abbreviation for read only memory.

### 1-2-2. Power Supply Circuit

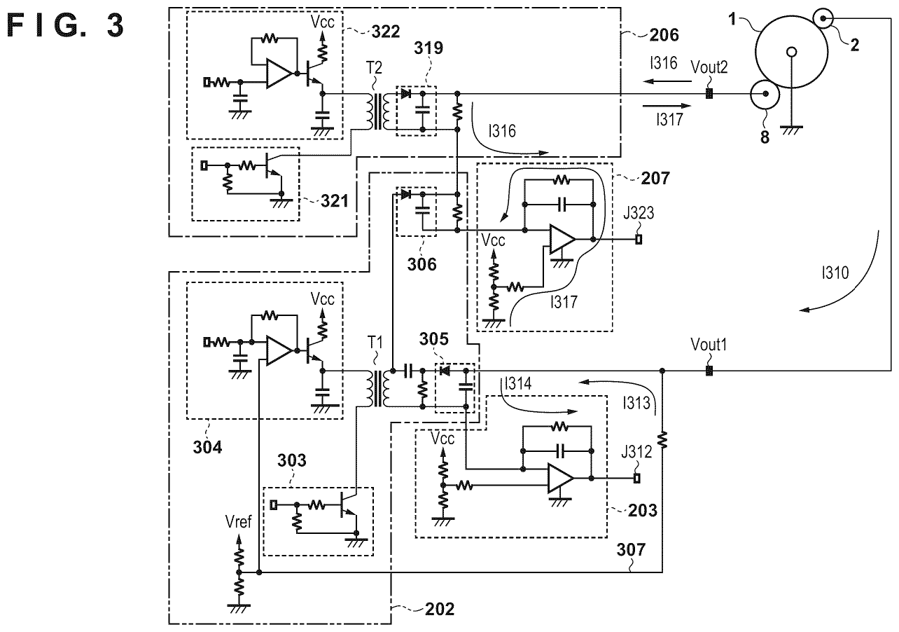

FIG. 3 is a circuit diagram illustrating an example of the power supply circuits 202 and 206. Vcc and Vref indicate reference voltage sources. The power supply circuit 202 includes a drive circuit 303, a voltage setting circuit 304, a transformer T2, and rectifier circuits 305 and 306. The voltage setting circuit 304 generates a primary side voltage corresponding to a voltage setting signal (e.g., a pulse width modulation (PWM) signal) output from the CPU 13, and applies the primary side voltage to one end of a primary winding of the transformer T1. A drive circuit 303 is connected to another end of the primary winding of the transformer T1. The drive circuit 303 switches and drives the transformer T1 based on an on/off signal (drive signal) output from the CPU 13.

As a result, a secondary side voltage is generated in a secondary winding of the transformer T1. A rectifier circuit 305 rectifies and smooths the secondary side voltage to generate an output voltage Vout1. The output voltage Vout1 is a high voltage of the negative polarity and is applied to the charging roller 2.

The secondary side voltage generated in the secondary winding of the transformer T1 is rectified and smoothed by another rectifier circuit 306, resulting in an output voltage of the negative polarity Vout2. The output voltage of the negative polarity Vout2 is applied to the transfer roller 8. As is clear from FIG. 2, the high voltage of the negative polarity generated by the power supply circuit 202 is applied to both the charging roller 2 and the transfer roller 8 simultaneously and in parallel.

A feedback circuit 307 is a circuit for feeding back the output voltage Vout1 to a voltage setting circuit 304. The voltage setting circuit 304 adjusts the primary side voltage of the transformer T1 so that a target voltage set by the CPU 13 matches the output voltage Vout1. In the first embodiment, for the sake of simplicity, the voltage output from the rectifier circuit 305 of the power supply circuit 202 and the voltage output from the rectifier circuit 306 coincide with each other.

The current detection circuit 203 includes, for example, an operational amplifier, a shunt resistor, a bypass capacitor, and the like. The current detection circuit 203 detects a current I314 that is a sum of a current I310 flowing through the charging roller 2 and a current I313 flowing from the feedback circuit 307. The current detection circuit 203 reports a detection result of the current I314 to the CPU 13 via a connecting point J312.

The power supply circuit 206 includes a drive circuit 321, a voltage setting circuit 322, a transformer T2, and a rectifier circuit 319. The voltage setting circuit 322 generates a primary side voltage corresponding to a voltage setting signal (e.g., a PWM signal) output from CPU 13, and applies the primary side voltage to one end of the primary winding of the transformer T2. A drive circuit 321 is connected to the other end of the primary winding of the transformer T2. The drive circuit 321 switches and drives the transformer T2 based on an on/off signal (drive signal) output from the CPU 13. As a result, a secondary side voltage is generated in the secondary winding of the transformer T2. A rectifier circuit 319 rectifies and smooths the secondary side voltage to generate a high voltage of the positive polarity (output voltage Vout2).

When the power supply circuit 202 and the power supply circuit 206 operate at the same time, the output voltage Vout2 is a superimposed voltage (superimposed bias) generated by superimposing a voltage of the negative polarity output from the power supply circuit 202 and a voltage of the positive polarity output from the power supply circuit 206.

The CPU 13 controls the voltage of the negative polarity generated by the power supply circuit 202 by supplying a voltage setting signal to the voltage setting circuit 304. The CPU 13 controls the voltage of the positive polarity generated by the power supply circuit 206 by supplying a voltage setting signal to the voltage setting circuit 322. That is, the CPU 13 can also control the superimposed bias.

The current detection circuit 207 includes, for example, an operational amplifier, a shunt resistor, a bypass capacitor, and the like. The current detection circuit 207 detects a current I316 flowing from the transfer roller 8 to the rectifier circuit 306, and reports the detection result to the CPU 13 through a connecting point J323. Similarly, the current detection circuit 207 detects a current I317 flowing from the power supply circuit 206 to the transfer roller 8, and reports the detection result to the CPU 13 through the connecting point J323. Here, the current I316 is a current generated when the power supply circuit 202 applies a voltage of the negative polarity to the transfer roller 8. The current I317 is a current generated when the power supply circuit 206 applies a voltage of the positive polarity to the transfer roller 8. When the power supply circuit 202 and the power supply circuit 206 operate at the same time and the superimposed bias is applied to the transfer roller 8, the current detection circuit 207 detects the current flowing through the transfer roller 8 and reports the detection result to the CPU 13. This current is a sum (difference) of the current I317 and the current I316.

### 1-2-3. Superimposed Bias

The positive transfer bias generated by the power supply circuit 206 is, for example, +3000 [V]. The negative transfer bias and the cleaning bias generated by the power supply circuit 202 are, for example, −1000 [V]. In this case, the superimposed bias applied to the transfer roller 8 at the time of image formation is +2000 [V]. Therefore, at the time of image formation, a charging bias of −1000 [V] is applied to the charging roller 2, and a transfer bias of +2000 [V] is applied to the transfer roller 8. At the time of cleaning, the output of the positive transfer bias is stopped, and a cleaning bias of −1000 [V] is applied to the transfer roller 8.

### 1-3. Current Detection Method

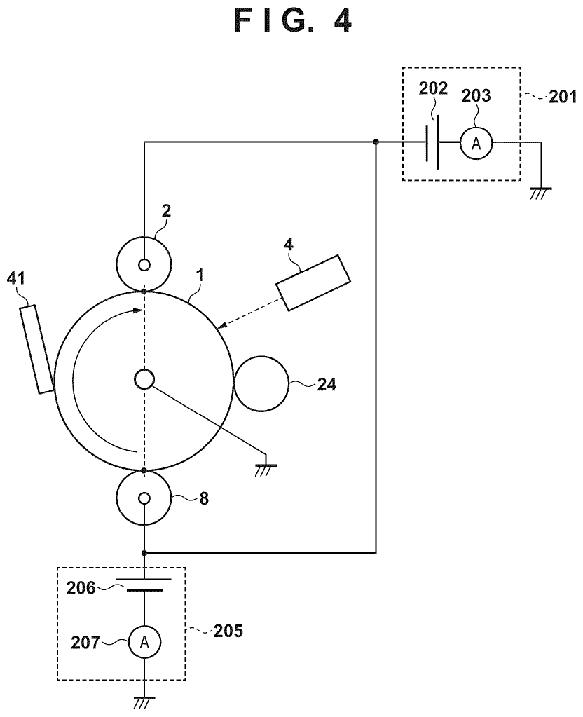

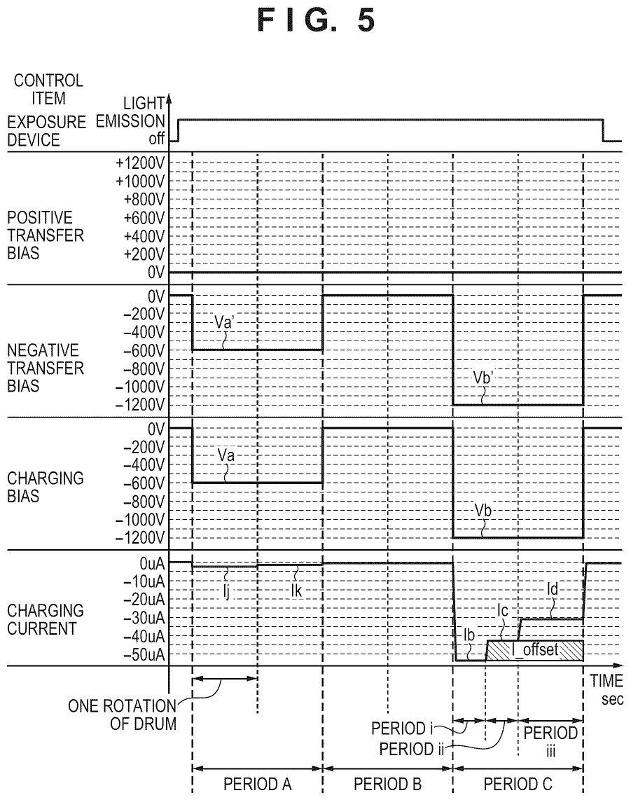

FIG. 4 shows a method of detecting a current flowing through the charging roller 2 in the first embodiment. FIG. 5 shows a detection sequence of a charging current and a charging potential in a comparative example. The exposure device 4 may always perform exposure while current detection is being performed.

When the photosensitive drum 1 is rotating, the power supply circuit 202 applies a direct current (DC) voltage of the negative polarity to the charging roller 2 and the transfer roller 8. The current detection circuit 203 detects a charging current flowing through the charging roller 2.

As illustrated in FIG. 5, periods A, B, and C are the time (two cycles) required for the photosensitive drum 1 to rotate two times, respectively.

The period A is the first current detection period. In the period A, a negative transfer bias Va′ is applied to the transfer roller 8, and a charging bias Va is applied to the charging roller 2. The period B is a standby period for returning the surface potential of the photosensitive drum 1 to 0 [V]. The period C is a second current detection period.

Here, Va′=Va=−600 [V] is used in the period A. The charging bias is −600 [V]. In the period B, Va′=Va=0 [V]. In period C, Va′=Va=−1200 [V] is obtained. Since the charging bias is −1200 [V], a large-scale electric discharge occurs. In the periods A to C, the positive transfer bias is not output.

In the period A, the surface portion of the photosensitive drum 1 having a surface potential of 0 [V] in the first rotation passes through the charging roller 2, so that a minute electric discharge occurs and a charging current Ij flows. The surface potential of the surface portion where the electric discharge occurred changes from 0 [V] to the dark portion potential VD. In this manner, the current detection circuit 203 detects the charging current Ij in the first rotation of the photosensitive drum 1. That is, the charging current Ij is detected in an uncharged surface portion. It is to be noted that a surface portion having the dark portion potential VD=−50 [V] is moved to the exposure position of the exposure device 4 by the rotation of the photosensitive drum 1. At the exposure position, the surface portion is irradiated with light, and the surface potential of the surface portion changes from the dark portion potential VD to the bright portion potential VL=0 to −50 [V]. Note that development and transfer are not performed.

When the surface portion having the surface potential of the bright portion potential VL passes through the charging roller 2 in the second rotation of the photosensitive drum 1, a minute electric discharge occurs, and a charging current Ik flows. The surface potential of the surface portion where the electric discharge occurs changes from the bright portion potential VL to the dark portion potential VD. Note that the potential difference between the bright portion potential VL and the charging bias is smaller than the potential difference between 0 [V] and the charging bias. Therefore, the charging current Ik is smaller than the charging current Ij.

In this manner, the current detection circuit 203 detects the charging current Ik in the second rotation of the photosensitive drum 1. In this case, the discharging current Ij is −3.16 [uA]. The discharging current is Ik=−2.18 [uA].

The unit “u” means micro.

In the period C, a charging bias Vb of −1200 [V] is applied to the charging roller 2. The negative transfer bias Vb′ is also −1200 [V]. The period C is divided into periods i to iii. The period i is a period in which a surface portion having a surface potential of 0 [V] passes through the charging roller 2. When the surface portion passes through the charging roller 2, an electric discharge occurs, a charging current Ib flows, and the surface potential changes from 0 [V] to the dark portion potential VD. The current detection circuit 203 detects the charging current Ib. In this case, Ib=−47.39 [uA]. The dark portion potential VD in the period C is −650 [V]. This is the bright portion potential VL=−90 [V].

The period ii is a period during which the surface portion having passed through the transfer roller 8 passes through the charging roller 2. This surface portion passes through the transfer roller 8 in the period i. Since a negative transfer bias Vb′ of −1200 [V] is also applied to the transfer roller 8, an electric discharge occurs. Thus, the surface potential of this surface portion is offset from 0 [V] to a negative predetermined potential. When the surface portion whose surface potential is a negative predetermined potential passes through the charging roller 2 in the period ii, an electric discharge occurs again, and a charging current Ic is detected. Since the surface potential of the surface portion that has passed through the transfer roller 8 is offset, the charging current Ic reduces by an offset current I_offset. In this example, Ic=−37.39 [uA]. I_offset is −10 [uA]. As described above, the discharging current Ib detected in the period i in the first rotation of the photosensitive drum 1 is different from the discharging current Ic detected in the period ii. |Ib|>|Ic|.

In the period iii, a surface portion of the surface portions having the bright portion potential VL=−90 [V] in which an electric discharge has occurred in the transfer roller 8 passes through the charging roller 2. As described above, since an electric discharge occurs when the surface portion passes through the transfer roller 8, the surface potential of the surface portion changes from −90 [V] to a negative predetermined potential. When the surface portion whose surface potential is a negative predetermined potential passes through the charging roller 2 in the period iii, an electric discharge occurs again, and the charging current Id is detected. |Ic|>|Id|. The charging current Id also decreases by the offset current I_offset. In this example, Id=−31.50 [uA].

As described above, it was found that when the charging bias and the negative transfer bias are shared, an error occurs in the detection result of the charging current. Therefore, in the first embodiment, even if the charging bias and the negative transfer bias are shared, a method of reducing an error between the detection result of the charging current in the first rotation of the photosensitive drum 1 and the detection result of the charging current in the second rotation is proposed.

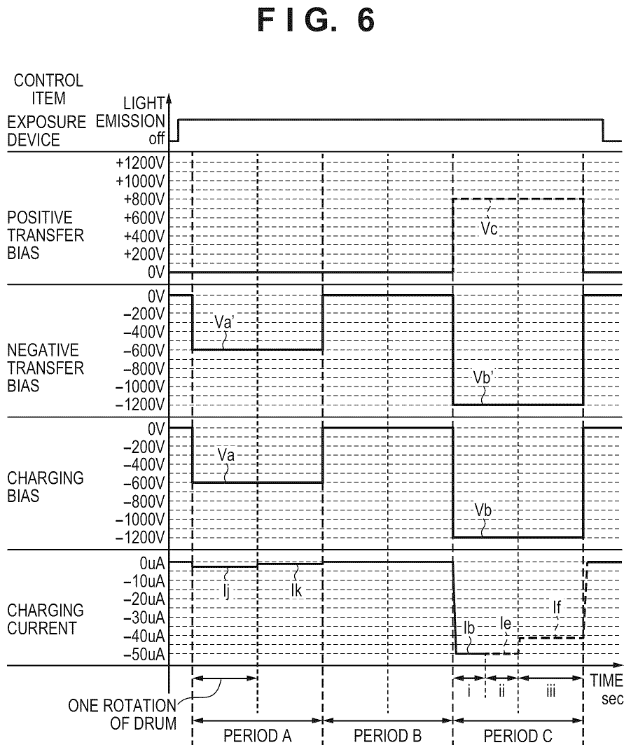

FIG. 6 shows a detection sequence of the charging current and the charging potential in the first embodiment. In FIG. 6, a difference from FIG. 5 is that the power supply circuit 206 is operated and the positive transfer bias Vc is output in the period C, so that the superimposed bias is applied to the transfer roller 8. In particular, the superimposed bias is adjusted to a voltage at which an electric discharge is less likely to occur between the surface of the photosensitive drum 1 and the transfer roller 8. For example, the positive transfer bias Vc is set to +800 [V]. The negative transfer bias Va′ is −1200 [V]. Therefore, the superimposed bias is −400 [V]. When the superimposed bias is −400 [V], no discharge occurs in the transfer roller 8 even if the surface potential is 0 [V]. Even when the surface potential is the dark portion potential VD, no discharging occurs in the transfer roller 8. Even when the surface potential is the bright portion potential VL, no electric discharge occurs in the transfer roller 8. That is, even if the surface portion passes through the transfer roller 8, the surface potential of the surface portion does not change.

As shown in FIG. 6, in the period i and the period ii, a surface portion having a surface potential of 0 [V] passes through the charging roller 2. Therefore, the charging current Ib detected in the period i coincides with a charging current Ie detected in the period ii. Charging current Ib=Ie=−47.39 [uA]. Therefore, it is confirmed that the offset current I_offset becomes 0 [uA].

In the period iii, the surface portion whose surface potential is the bright portion potential VL passes through the charging roller 2. Therefore, a charging current If detected in the period iii becomes constant. The discharging current If=−41.50 [uA] was obtained. Again, the offset current I_offset is 0 [uA].

According to the first embodiment, in the detection period of the discharging current (charging current), the positive transfer bias is superimposed on the negative transfer bias, so that the superimposed bias is generated and applied to the transfer roller 8. As a result, the electric discharge at the transfer roller 8 which becomes disturbance is reduced, and the charging current flowing through the charging roller 2 can be accurately detected.

Further, there is a method of estimating an electric discharge start voltage by detecting a discharging current flowing in the charging roller 2 while gradually changing a high voltage applied to the charging roller 2. Compared to this approach, the first embodiment uses two voltages −600V, −1200V as the charging bias so that the charging current can be detected in a short time.

### 1-4. Method of Calculating Charging Potential

The CPU 13 calculates the surface potential (charging potential) of the photosensitive drum 1 by using the following mathematical expression. As the charging potential, the dark portion potential VD and the bright portion potential VL are calculated. These are required in order to accurately control Vcont and Vback.

$$\begin{matrix}I = ( \vert Ib \vert - \vert Ij \vert ) \div ( \vert Vb \vert - \vert Va \vert ) \\ = ( 47.39 [ uA ] - 3.16 [ uA ] ) \div ( 1200 [ V ] - 600 [ V ] ) \\ = 0.073463 [ \text{uA/V} ]\end{matrix} \qquad Eq1$$

Here, i is a discharging current flowing through the charging roller 2 when the charging bias changes by 1V. That is, i represents the current change amount per a unit voltage. Ib is the charging current detected in the period i within the period C. Ij is a charging current detected in the first rotation of the photosensitive drum 1 in the period A. Va is the charging bias in the period A. Vb is the charging bias in the period C.

Next, the CPU 13 calculates the dark portion potential VD and the bright portion potential VL using the following mathematical expression.

$$\begin{matrix}V D = \vert Ib \vert \div i \\ = 47.39 [ uA ] \div 0.073463 [ \text{uA/V} ] \\ = 645.1 [ V ]\end{matrix} \qquad Eq2$$

$$\begin{matrix}V L = V D - \vert If \vert \div i \\ = 645.1 [ V ] - 41.5 [ uA ] \div 0.073463 [ \text{uA/V} ] \\ = 80.1 [ V ]\end{matrix} \qquad Eq3$$

Here, If is a discharging current detected in the period iii.

As described above, the measured value of the dark portion potential VD is −650 [V]. The calculated value of the dark portion potential VD is −645.1 [V]. The measured value of the bright portion potential VL is −90 [V]. The calculated value of the bright portion potential VL is −80.1 [V]. Therefore, it can be said that the error is sufficiently small. Therefore, in the first embodiment, the charging potential can be accurately obtained in a short time.

### 1-5. Flowchart

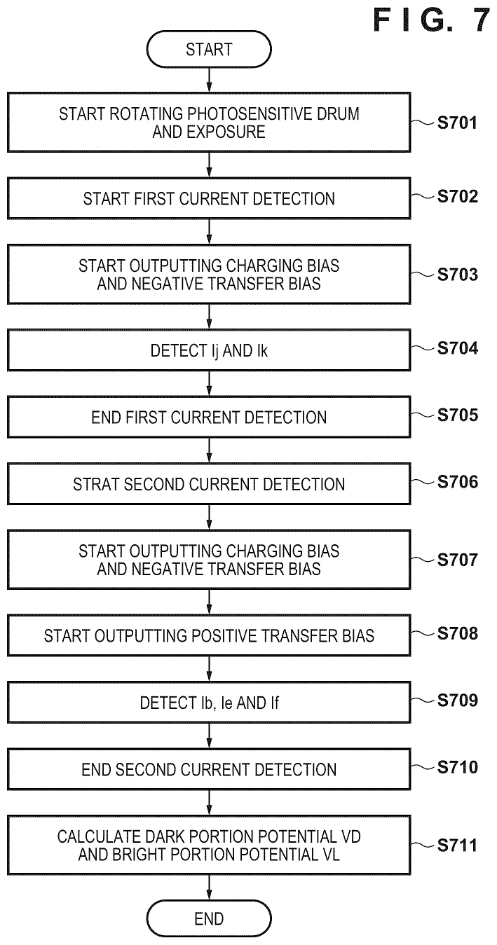

FIG. 7 shows a detection method of the surface potential performed by the CPU 13 according to the control program.

In S701, the CPU 13 starts rotating the photosensitive drum 1 and exposing by the exposure device 4. For example, the CPU 13 instructs the drive circuit 208 to rotate the motor M1. The drive circuit 208 starts driving the motor M1 in accordance with the rotational instruction. The motor M1 starts rotating the photosensitive drum 1. Note that the rotation start of the photosensitive drum 1 and the exposure start of the exposure device 4 may be deviated from each other. Note that the rotation start timing of the photosensitive drum 1 is preferably earlier than the exposure start timing of the exposure device 4.

In S702, the CPU 13 starts the first current detection.

In S703, the CPU 13 activates the power supply circuit 202 to start outputting the charging bias Va and the negative transfer bias Va′.

For example, the charging bias Va and the negative transfer bias Va′ are each −600 [V].

In S704, the CPU 13 detects the charging current Ij and the charging current Ik. For example, the CPU 13 may convert an analog detection result output from the current detection circuit 203 into a digital value, and obtain a mean value of a plurality of digital values (sampled values) as the charging current Ij. In some cases, the charging current Ik is not used to determine the charging potential as in the above described mathematical expression. In this case, the acquisition of the charging current Ik may be omitted.

In S705, the CPU 13 ends the first current detection. The CPU 13 stores the charging currents Ij, Ik in a RAM area of the memory 15. RAM is an abbreviation for random access memory. The CPU 13 stops the power supply circuit 202 and restores the surface potential of the photosensitive drum 1 to 0 [V].

In S706, the CPU 13 starts the second current detection. The CPU 13 ensures a period B between the steps S705 and S706, and returns the surface potential of the photosensitive drum 1 to 0 [V].

In S707, the CPU 13 activates the power supply circuit 202 to start outputting the charging bias Vb and the negative transfer bias Vb′. For example, the charging bias Vb and the negative transfer bias Vb′ are each −1200 [V].

In S708, the CPU 13 activates the power supply circuit 206 to start outputting the positive transfer bias Vc. The positive transfer bias Vc is, for example, +800 [V]. In S707, it is preferable that the positive transfer bias Vc be output prior to reaching the transfer nip of the surface portion to which the charging bias Vb is applied. S707 and S708 may be executed simultaneously.

In S709, the CPU 13 detects the charging currents Ib, Ie, and Ik. For example, the CPU 13 may convert an analog detection result output from the current detection circuit 203 into a digital value, and obtain a mean value of a plurality of digital values (sampled values) as the charging currents Ib, Ie, and If. In some cases, the charging current Ie is not used as in the above described mathematical expression. In this case, the acquisition of the charging current Ie may be omitted.

In S710, the CPU 13 ends the second current detection. The CPU 13 stores the charging currents Ib, Ie, and If in the RAM area of the memory 15. In addition, the CPU 13 stops the power supply circuits 202 and 206, the exposure device 4, and the motor M1.

In S711, the CPU 13 calculates the dark portion potential VD and the bright portion potential VL. The CPU 13 may obtain the dark portion potential VD and the bright portion potential VL by reading the detection result from the memory 15 and applying the detection result to the mathematical expressions Eq1 to Eq3.

According to the first embodiment, in the image forming apparatus 100 in which the charging bias and the negative transfer bias are simultaneously generated, the charging potential of the photosensitive drum 1 can be preferably obtained. Specifically, when the discharging current (charging current) flowing through the charging roller 2 is detected, a superimposed bias is applied to the transfer roller 8 so that an electric discharge is less likely to occur in the transfer roller 8. Here, the superimposed bias is generated by superimposing the positive transfer bias on the negative transfer bias.

A charging bias Va of −600 [V] was adopted as the period A, and −1200 [V] was used as the charging bias Vb of the period C, but these are merely examples. The charging bias Va and Vb may be increased or decreased as long as the detection result of the charging potential is accurately obtained.

As an example of the superimposed bias, +800 [V] was adopted. However, this is just an example. It is possible to adopt a superimposed bias in which an electric discharge is unlikely to occur between the surface of the photosensitive drum 1 and the transfer roller 8. Therefore, the superimposed bias may be higher or lower than +800 [V].

### 2. Second Exemplary Embodiment

In the first embodiment, a positive transfer bias Vc of a fixed value is output in the period C in order to generate a superimposed bias that does not cause an electric discharge between the photosensitive drum 1 and the transfer roller 8. However, the positive transfer bias Vc may be variable value. A resistance value of the transfer roller 8 varies depending on the environment (e.g., temperature, humidity, and atmospheric water content). That is, the conditions under which the electric discharge occurs depend on the environment. Therefore, in the second embodiment, the positive transfer bias Vc is adjusted according to the environmental condition in which the image forming apparatus 100 is installed. That is, the superimposed bias is adjusted.

### 2-1. Characteristics of the Transfer Roller

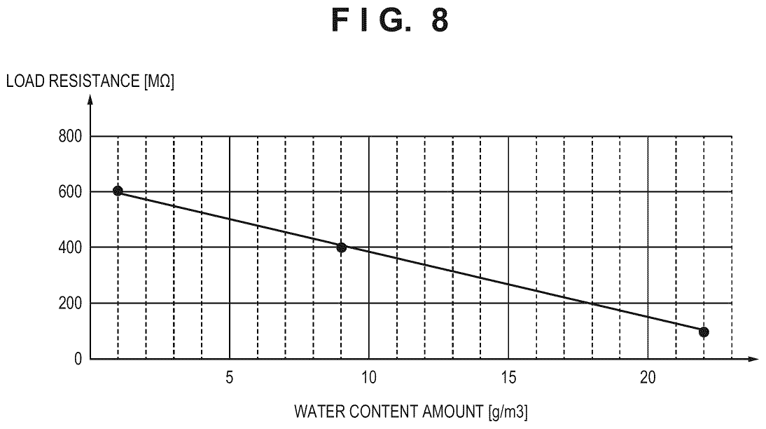

FIG. 8 shows environmental characteristics of the transfer roller 8. The vertical axis represents a load resistance [MΩ] of the transfer roller 8. The horizontal axis shows a water content [g/m³]. The unit “m³” means cubic meter. As shown in FIG. 8, the load resistance of the transfer roller 8 changes depending on an amount of water content in the atmosphere in which the transfer roller 8 is placed. Therefore, the CPU 13 determines the transfer bias to be supplied to the transfer roller 8 in accordance with the current detected by the current detection circuit 207.

2-2. Method for Controlling a Positive Transfer Bias that Forms Part of a Superimposed Bias

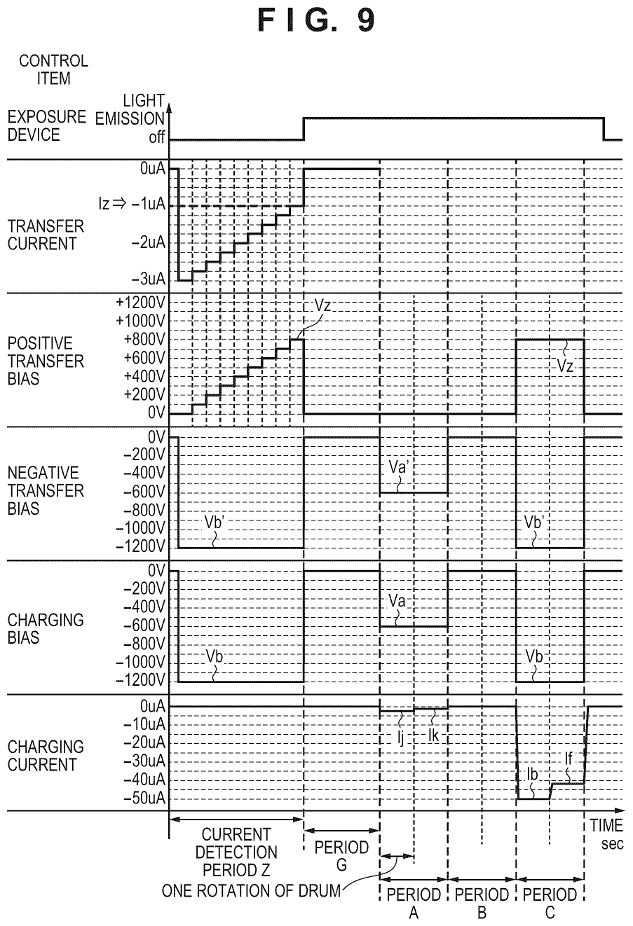

FIG. 9 shows a method for controlling the superimposed bias applied to the transfer roller 8 in the second embodiment. As an illustration, the water content is assumed to be 9.0 [g/m³]. The resistance value of the transfer roller 8 is assumed to be 400 [MΩ].

In this example, a current detection period Z (hereinafter, abbreviated as “period Z”) and a period G are added before the period A. The period Z is a period in which a transfer current flowing between the transfer roller 8 and the photosensitive drum 1 is detected and the transfer bias is adjusted so that the detected transfer current becomes a target value Iz. The period G is a standby period for returning the surface potential of the photosensitive drum 1 to 0 [V].

In the period Z, the CPU 13 controls the power supply circuit 202 so that the charging bias Vb and the negative transfer bias Vb′ are simultaneously output.

Here, the charging bias Vb and the negative transfer bias Vb′ output in the period Z are the same as the charging bias Vb and the negative transfer bias Vb′ in the period C. The target value Iz is determined in advance based on environmental conditions, and is stored in the ROM area of the memory 15. Here, Iz is assumed to be −1.0 [uA].

The CPU 13 compares the transfer current detected by the current detection circuit 207 with the target value Iz and incrementally increments the positive transfer bias until both coincide. For example, the positive transfer bias Vz when the transfer current reached the target value Iz was +800 [V]. The CPU 13 stores the positive transfer bias Vz in the RAM area of the memory 15. In the period C, the CPU 13 reads the positive transfer bias Vz from the memory 15 and causes the power supply circuit 206 to provide the positive transfer bias Vz. During the period C, the CPU 13 controls the power supply circuit 202 to also provide the charging bias Vb and the negative transfer bias Vb′. As a result, a superimposed bias, which is the sum of the positive transfer bias Vz and the negative transfer bias Vb′, is applied to the transfer roller 8. As a result, an electric discharge is less likely to occur between the transfer roller 8 and the photosensitive drum 1. The time length of the period Z is, for example, a time of about 3 seconds to 5 seconds. When the period Z ends, the CPU 13 waits for the period G to elapse. When the period G expires, the CPU 13 proceeds to the periods A to C described in the first embodiment.

### 2-3. A Method for Determining the Target Value Iz

The resistance value of the transfer roller 8 varies depending on an amount of atmospheric water content. Thus, the target value Iz should be determined or selected depending on the atmospheric water content. For example, the ROM area of the memory 15 may store a table that holds target value Iz for various amounts of water content. This table is determined in advance by experimentation or simulation. The CPU 13 obtains, from the table, target value Iz corresponding to the amount of water content detected by the environmental sensor 26. This table may be implemented by a mathematical function or program module which takes the water content as input and the target value Iz as output. The resistance value of the transfer roller 8 may be adopted instead of the water content. Instead of the amount of water content, the temperature and the humidity detected by the environmental sensor 26 may be adopted.

For example, if the water content is less than 5.8 [g/m³], the target value Iz is determined to be −0.7 [uA]. If the water content is equal to or larger than 5.8 [g/m³] and less than 18 [g/m³], the target value Iz is determined to be −1.0 [uA]. If the water content is equal to or larger than 18 [g/m³], the target value Iz is determined to be −4.0 [uA]. The table holds the correspondence between the water content and the target value Iz.

If the detection result of the environmental sensor 26 is 1.0 [g/m³], the CPU 13 refers to the table and determines that the target value Iz is −0.7 [uA]. According to FIG. 8, the resistance value of the transfer roller 8 is 600 [MΩ]. The positive transfer bias Vz when the transfer current reaches −0.7 [uA] which is the target value Iz is obtained from the following mathematical expression.

$$\begin{matrix}Vz = - Vb + ( - 0.7 [ uA ] \times 600 [ MΩ ] ) \\ = - ( - 1 \; 200 [ V ] ) - 420 [ V ] \\ = + 780 [ V ]\end{matrix} \qquad Eq4$$

If the detection result of the environmental sensor 26 is 22 [g/m³], the CPU 13 refers to the table and determines the target value Iz as −4.0 [uA]. According to FIG. 8, the resistance value of the transfer roller 8 is 100 [MΩ]. The positive transfer bias Vz when the transfer current reaches −4.0 [uA] which is the target value Iz is obtained from the following mathematical expression.

$$\begin{matrix}Vz = - Vb + ( - 4. [ uA ] \times 100 [ MΩ ] ) \\ = - ( - 1 \; 200 [ V ] ) - 400 [ V ] \\ = + 800 [ V ]\end{matrix} \qquad Eq5$$

The target value Iz may be stored in the memory 15 or may be stored in the non-volatile memory 30 provided in the process cartridge 22. The CPU 13 reads the target value Iz corresponding to the water content from the non-volatile memory 30.

### 2-4. Flowchart

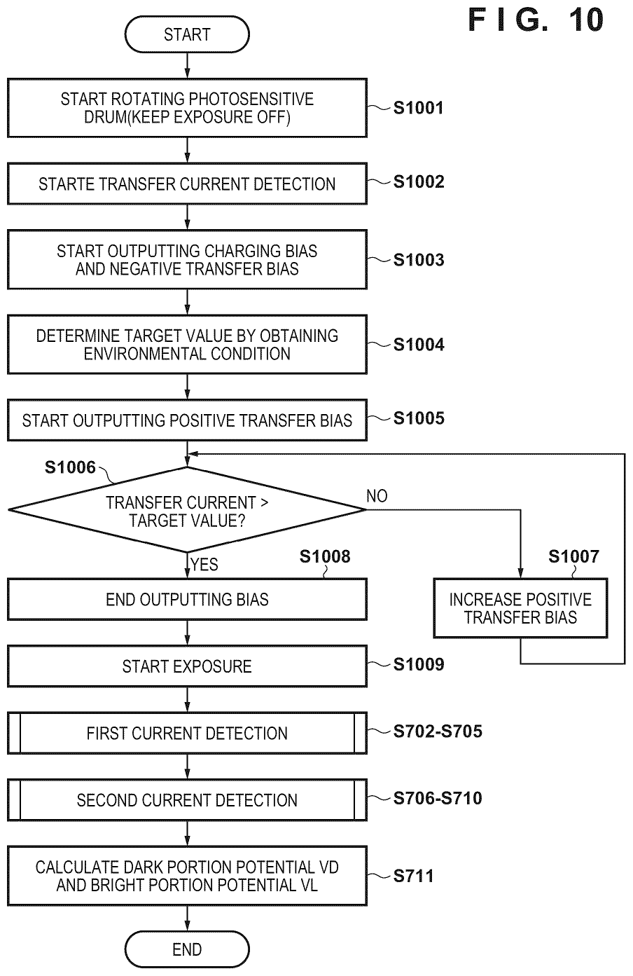

FIG. 10 shows a method for control according to the second embodiment. In FIG. 10, the same reference numerals are given to the same steps as those in FIG. 7, and the description thereof will be omitted.

In S1001, the CPU 13 starts the motor M1 through the drive circuit 208 and starts rotating the photosensitive drum 1. The exposure device 4 is kept off.

In S1002, the CPU 13 activates the current detection circuit 207 to start detecting the transfer current.

In S1003, the CPU 13 activates the power supply circuit 202 and starts outputting the charging bias Vb and the negative transfer bias Vb′. The charging bias Vb and the negative transfer bias Vb′ are, for example, −1200 [V].

In S1004, the CPU 13 uses the environmental sensor 26 to detect environmental conditions (e.g., water content) and determines a target value Iz based on the environmental conditions. The environmental condition may be any parameter that can detect the electric resistance value of the transfer roller 8.

The CPU 13 determines a target value Iz corresponding to the environmental condition based on a table, a mathematical function, or a program module stored in the memory 15 or the non-volatile memory 30. For example, if the water content is 9 [g/m³], the target value Iz is determined to be −1 [uA].

S1004 may be performed prior to S1003.

In S1005, the CPU 13 activates the power supply circuit 206 to start outputting positive transfer bias.

In S1006, the CPU 13 detects the transfer current using the current detection circuit 207 and determines whether the transfer current has exceeded the target value Iz. If the transfer current does not exceed the target value Iz, the CPU 13 proceeds from S1006 to S1007. In S1007, the CPU 13 increases the positive transfer bias in one step (e.g., +100 [V]). The CPU 13 then proceeds from S1007 to S1006. When it is determined that the transfer current has reached the target value Iz in S1006, the CPU 13 proceeds from S1006 to S1008. In the present embodiment, the determination as to whether or not a certain measured value exceeds a threshold value may be read as a determination as to whether or not a certain measured value becomes equal to or larger than a threshold value. Similarly, a determination as to whether a certain measured value has fallen below a threshold value may be read as a determination as to whether a certain measured value has fallen below the threshold value. In addition, in a case where the i-th current value exceeds the threshold value among the plurality of measured values (current values) arranged in time series, a voltage value corresponding to the i-th current value may be adopted. Alternatively, a voltage value corresponding to i−1-th current value that does not exceed the threshold value may be employed.

The voltage value corresponding to the threshold value may be calculated by linearly interpolating i−1-th current value and the i-th current value. The concepts associated with such comparisons apply not only to S1006 but also to other steps.

In S1008, the CPU 13 ends outputting the bias (positive transfer bias, charging bias Vb, and negative transfer bias Vb′).

In S1009, the CPU 13 starts the exposure device 4 and causes the exposure device 4 to start exposure. Note that S1008 and S1009 may be executed substantially simultaneously. The CPU 13 then executes S711 from S702. Note that CPU 13 secures the period G between S1009 and S702.

The second embodiment can exhibit the same effects as those of the first embodiment. Further, in the second embodiment, the positive transfer bias is adjusted according to the environmental conditions. Therefore, in the method of determining the surface potential of the photosensitive drum 1, the superimposed bias is accurately adjusted so that an electric discharge is less likely to occur at the transfer nip. As a result, the second embodiment will be able to determine the surface potential more accurately than the first embodiment.

### 3. Third Exemplary Embodiment

In the first embodiment, the superimposed bias in which an electric discharge is unlikely to occur between the photosensitive drum 1 and the transfer roller 8 is a fixed value. The superimposed bias of the second embodiment was a variable value that varied depending on the environmental conditions. The third embodiment proposes a method for reducing the time for determining the superimposed bias and the positive transfer bias.

### 3-1. Dark Decay of the Charging Potential

As the photosensitive drum 1 rotates, the surface portion of the photosensitive drum 1 passes through the contact portion (charging nip) with the charging roller 2. As the surface portion passes through the charging nip, the surface potential (charging potential) of the surface portion decays. This phenomenon is called dark decay.

As illustrated in FIG. 9, in the period A of the second embodiment, the charging current when the charging potential changes from 0 [V] to the dark portion potential VD is detected in the first rotation of the photosensitive drum 1. In the period Z, a charging bias of −1200 [V] is applied to the charging roller 2. Therefore, the period G for returning the surface potential to 0 [V] due to dark decay is required between the period Z and the period A. Therefore, if the period G is shortened, the determination time of the charging potential is shortened as a whole.

### 3-2. Method of Shortening

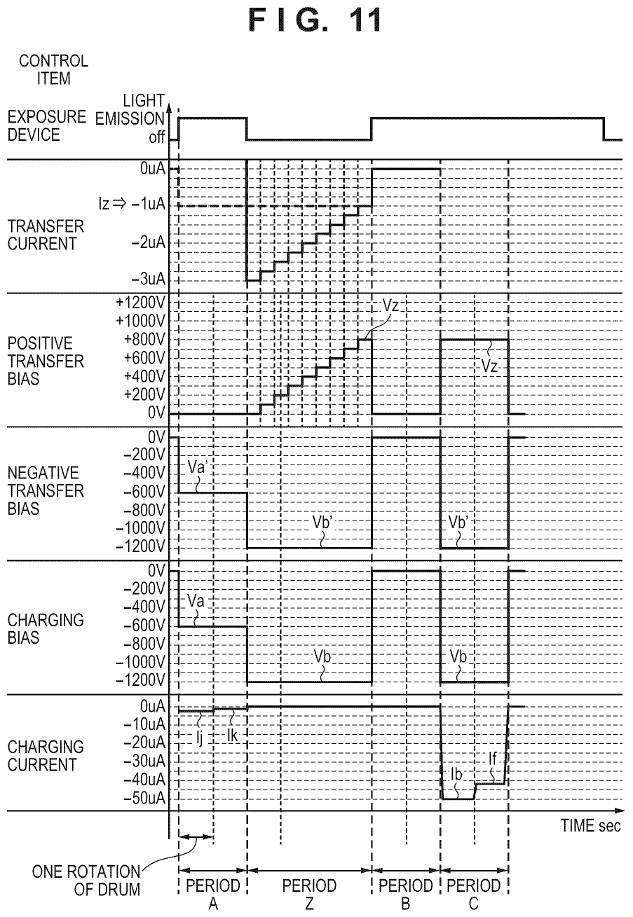

FIG. 11 shows a charging potential detection method according to a third embodiment. For example, the water content is 9.0 [g/m³], and the resistance value of the transfer roller 8 is assumed to be 400 [MΩ]. When FIG. 11 is compared with FIG. 9, in FIG. 11, the period Z is arranged between the period A and the period B, and the period G is omitted. That is, the period B functions as the period G.

In the period A, the charging bias Va and the negative transfer bias Va′ are simultaneously output. At the first rotation of the photosensitive drum 1, the charging current Ij when the charging potential changes from 0 [V] to the dark portion potential VD is detected. At the second rotation of the photosensitive drum 1, the charging current Ik when the charging potential changes from the bright portion potential VL to the dark portion potential VD is detected. Then, the CPU 13 transitions from the period A to the period Z.

The charging bias Vb in the period Z is the same as the charging bias Vb in the period C. The negative transfer bias Vb′ in period Z is the same as the negative transfer bias Vb′ in the period C. The target value Iz of the transfer current in the period Z is determined on the basis of the table described in the second embodiment. For example, if the water content is 9.0 [g/m³], the target value Iz is determined to be −1.0 [uA]. The CPU 13 incrementally increases the positive transfer bias until the transfer current detected by the current detection circuit 207 is −1.0 [uA]. The CPU 13 stores the positive transfer bias Vz (e.g., +800 [V]) in the memory 15 when the transfer current reaches the target value Iz. In the period C, the CPU 13 reads the positive transfer bias Vz from the memory 15, superimposes the positive transfer bias Vz on the negative transfer bias to generate a superimposed bias, and applies the superimposed bias to the transfer roller 8. Thus, in the period C, an electric discharge from the transfer roller 8 to the photosensitive drum 1 is suppressed.

### 3-3. Flowchart

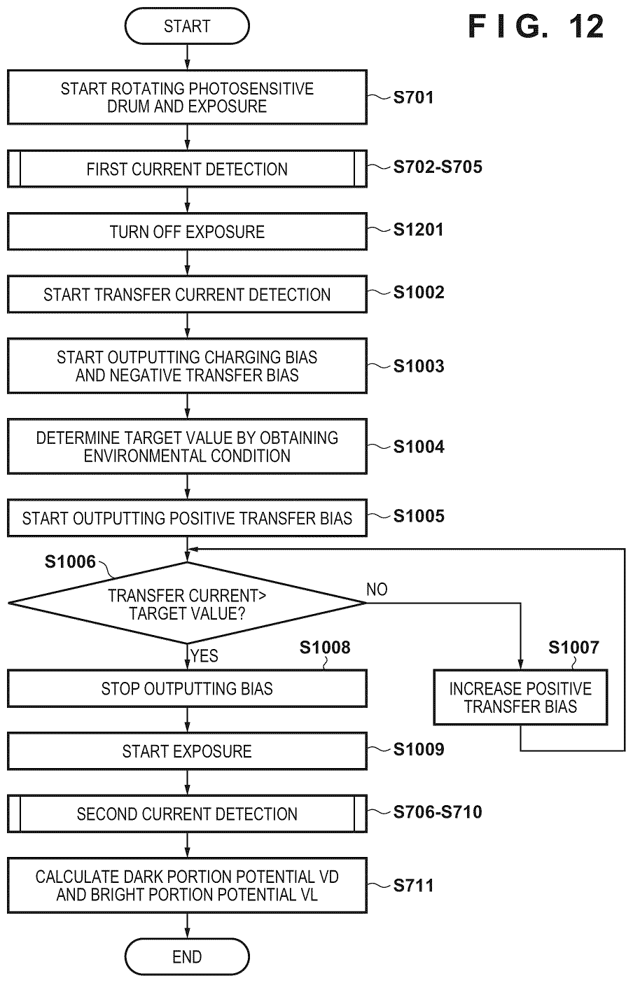

FIG. 12 shows a method of detecting a charging potential in the third embodiment. The steps already described are given the same reference numerals.

The CPU 13 executes the steps S701 to S705. As a result, the detection of the first charging current is completed. The CPU 13 then proceeds from S705 to S1201.

In S1201, the CPU 13 controls the exposure device 4 and turns off the exposure in order to adjust the superimposed bias. The CPU 13 proceeds from S1201 to S1002 described in the second embodiment.

The CPU 13 executes the steps S1002 to S1009. Accordingly, the positive transfer bias Vz when the transfer current reaches the target value Iz is determined. Thereafter, the CPU 13 proceeds from S1009 to S706 and executes the steps S706 to S710 (second detection of the charging current). It should be noted that the CPU 13 ensures the period B between S1009 and S706.

As described above, the period Z (adjustment of the superimposed bias) is performed between the period A (first detection of the charging current) and the period B. As a result, the period G and the period B are integrated, and as a whole, the time required for the charging potential detection method is shortened.

Other effects of the third embodiment are the same as those of the second embodiment.

### 4. Fourth Exemplary Embodiment

The fourth embodiment is intended to further shorten a processing time than the third embodiment. Specifically, in the fourth embodiment, the adjustment of the superimposed bias (period Z) is performed within the period A. That is, the first detection of the charging current and the adjustment of the superimposed bias are performed in parallel.

### 4-1. Processing Time Reduction Method

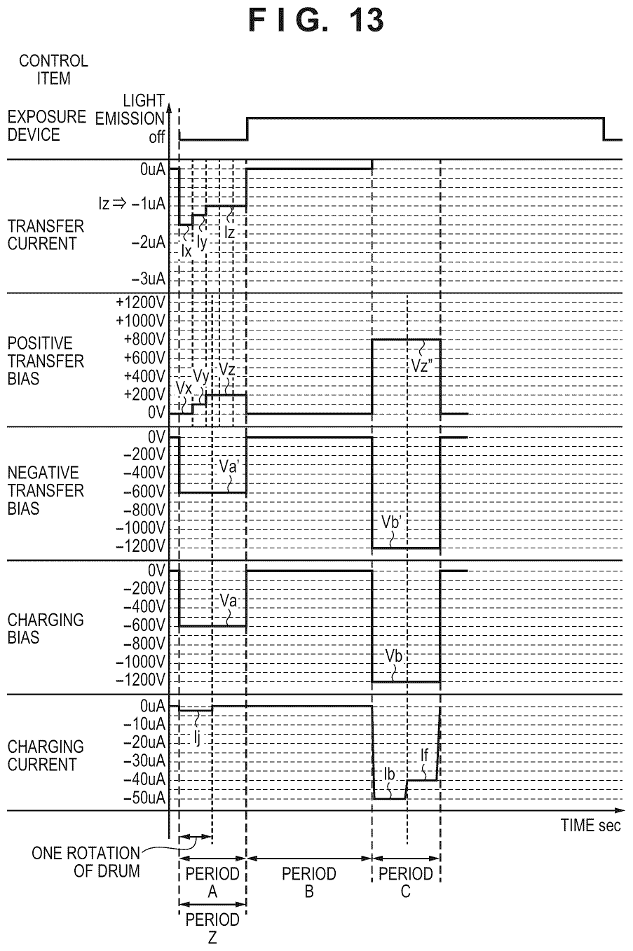

FIG. 13 shows a method of detecting a charging potential in the fourth embodiment. As already explained in FIG. 9 (second embodiment), in the time period Z, the charging bias Vb and the output start of the negative transfer bias Vb (e.g., −1200 [V]) are earlier than the output start of the positive transfer bias. When the negative transfer bias Vb′ is applied and no positive transfer bias is applied, the transfer current is, for example, −3.0 [uA]. The target value Iz in the period Z is, for example, −1.0 [uA]. Thus, the CPU 13 can incrementally increase the positive transfer bias until the transfer current detected by the current detection circuit 207 reaches the target value Iz.

When the charging bias Va and the negative transfer bias Va′ are −600 [V], the dark portion potential VD of the photosensitive drum 1 is −50 [V]. In this state, only a minute electric discharge occurs from the transfer roller 8 to the photosensitive drum 1. Further, the charging current Ij flowing through the charging roller 2 becomes −3.16 [uA]. Here, there is a difference between the charging current flowing when the surface portion of the transfer roller 8 that is not affected by the electric discharge passes through the charging roller 2 and the charging current flowing when the surface portion of the transfer roller 8 that is affected by the electric discharge passes through the charging roller 2. However, when the charging bias Va and the negative transfer bias Va′ are respectively −600 [V], the discharging amount is small. Therefore, the difference Δ of the charging current is only 0.15 [uA]. In the first embodiment, the difference Δ may be converted into a difference ΔVD between the dark portion potential VD and a difference ΔVL between the bright portion potential VL when the charging bias Vb and the negative transfer bias Vb′ are respectively −1200 [V]. In this case, ΔVD is 2 [V] and ΔVL is 0.3 [V]. Thus, these differences will be negligible. That is, as shown in FIG. 13, in the fourth embodiment, the period A and the period Z are superimposed.

In period A (period A also serves as period Z), the charging bias Va and the negative transfer bias Va′ are output at the same time. At this time, the transfer current flowing through the transfer roller 8 is −1.5 [uA]. As described in the second embodiment, the target value Iz when the water content is 9.0 [g/m³] is −1.0 [uA]. Thus, the CPU 13 increments the positive transfer bias step by step until the transfer current detected by the current detection circuit 207 reaches the target value Iz. The positive transfer bias Vz when the transfer current reaches the target value Iz is +200 [V]. At this time, the superimposed bias may be calculated based on the following mathematical expression.

$$\begin{matrix}Superimposed bias {Vx}^{′} = negative transfer bias {Va}^{′} + \\ positive transfer bias Vx \\ = - 600 + 0 \\ = - 600 [ V ]\end{matrix} \qquad Eq6$$

$$\begin{matrix}Superimposed bias {Vy}^{′} = negative transfer bias {Va}^{′} + \\ positive transfer bias Vy \\ = - 600 + 100 \\ = - 500 [ V ]\end{matrix} \qquad Eq7$$

$$\begin{matrix}Superimposed bias {Vz}^{′} = negative transfer bias {Va}^{′} + \\ positive transfer bias Vz \\ = - 600 + 200 \\ = - 400 [ V ]\end{matrix} \qquad Eq8$$

The transfer currents Ix, Iy, and Iz corresponding to the superimposed biases Vx′, Vy′, and Vz′ can be computed from the following mathematical expression:

$$\begin{matrix}Ix = - 600 [ V ] \div 400 [ MΩ ] \\ = - 1.5 [ uA ]\end{matrix} \qquad Eq9$$

$$\begin{matrix}Iy = - 500 [ V ] \div 400 [ MΩ ] \\ = - 1.25 [ uA ]\end{matrix} \qquad Eq10$$

$$\begin{matrix}Iz = - 400 [ V ] \div 400 [ MΩ ] \\ = - 1. [ uA ]\end{matrix} \qquad Eq11$$

The charging bias Va and the negative transfer bias Va′ were −600 [V], respectively, during the time period in which the positive transfer bias Vz was determined to be +200 [V]. The charging bias Vb and the negative transfer bias Vb′ applied in period C are =−1200 [V], respectively. Therefore, the positive transfer bias Vz in the period C is determined by adding the difference between Va and Vb to Vz.

$$\begin{matrix}{Vz}^{″} = Vz + ( Va - Vb ) \\ = 200 + ( - 6 \; 00 - ( - 1200 ) ) \\ = + 800 [ V ]\end{matrix} \qquad Eq12$$

### 4-2. Flowchart

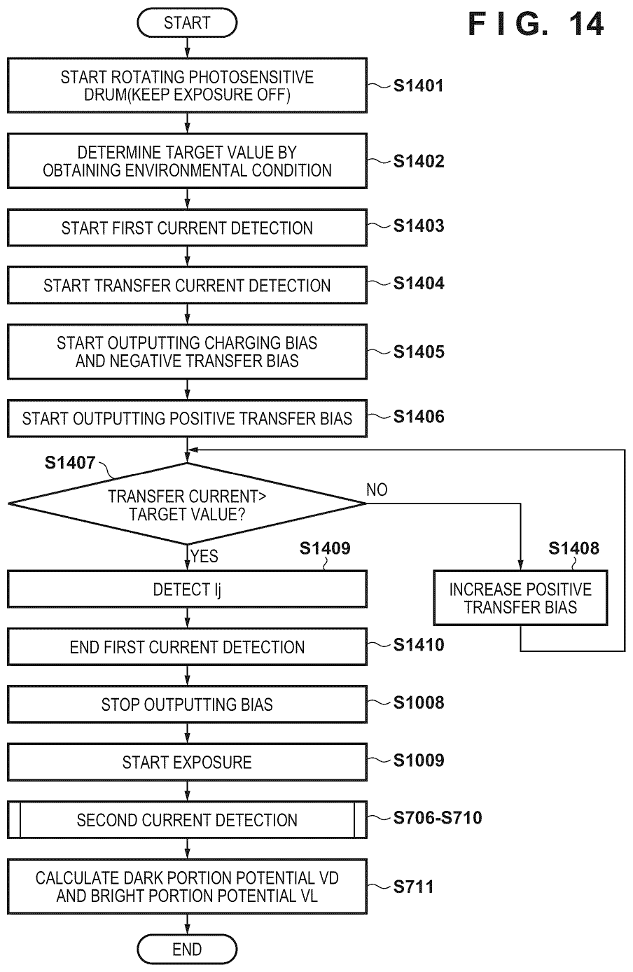

FIG. 14 shows a charging potential detection method according to the fourth embodiment. The steps already described are given the same reference numerals.

In S1401, the CPU 13 starts the motor M1 through the drive circuit 208 and starts rotating the photosensitive drum 1. At this point, the exposure device 4 keeps the exposure off.

In S1402, the CPU 13 acquires an environmental condition using the environmental sensor 26, and determines the target value Iz of the transfer current based on the environmental condition. For example, the CPU 13 refers to the table based on the environmental condition (atmospheric water content) and acquires the target value Iz corresponding to the environmental condition.

In S1403, the CPU 13 activates the current detection circuit 203 to start a first detection of the charging current.

In S1404, the CPU 13 activates the current detection circuit 207 to start detecting the transfer current.

In S1405, the CPU 13 activates the power supply circuit 202 to start outputting the charging bias Va and the negative transfer bias Va′.

In S1406, the CPU 13 activates the power supply circuit 206 to start outputting positive transfer bias.

In S1407, the CPU 13 detects the transfer current using the current detection circuit 207 and determines whether the transfer current has exceeded the target value Iz. If the transfer current does not exceed the target value Iz, the CPU 13 proceeds from S1407 to S1408. In S1408, the CPU 13 increases the positive transfer bias in one step. The CPU 13 then proceeds from S1408 to S1407. In S1407, if it is determined that the transfer current exceeds the target value Iz, the CPU 13 proceeds from S1407 to S1409.

In S1409, the CPU 13 detects the charging current Ij using the current detection circuit 203. In S1410, the CPU 13 ends the first detection of the charging current. The CPU 13 then performs S1008, S1009, and S706 to S711 described in FIG. 12. However, the positive transfer bias used in S708 is the positive transfer bias Vz determined in S1407 and S1408. In S709, the charging currents Ib, and If are detected. The CPU 13 ensures the period B between S1009 and S706.

In the fourth embodiment, the period A and the period Z are superimposed. Therefore, in the fourth embodiment, the processing time can be further shortened than in the third embodiment. Other effects of the fourth embodiment are the same as those of the third embodiment.

In the first to fourth embodiments, since the polarity of the toner Tis negative, the charging bias and the negative transfer bias are negative and the positive transfer bias is positive. However, if the polarity of the toner T is positive, the polarity of these biases will be opposite.

### 5. Other Embodiment

The charging roller 2 is an example of a charging member that charges the surface of the photosensitive drum 1 that is rotationally driven by the motor M1. The developing roller 24 is an example of a developing member that develops an electrostatic latent image using toner T charged to a first polarity (e.g., negative polarity) to form a toner image. The transfer roller 8 is an example of a transfer member that transfers a toner image from the photosensitive drum 1 to a transfer material (for example, a sheet P or an intermediate transfer member). The power supply circuit 202 is an example of a first power supply that generates a voltage of a first polarity, supplies the voltage of the first polarity to the charging roller 2 as a charging bias, and outputs the voltage of the first polarity to the transfer roller 8. The voltage of the first polarity applied to the transfer roller 8 may be a so-called cleaning bias. The power supply circuit 206 is an example of a second power supply that generates a voltage of a second polarity opposite to the first polarity and supplies the voltage of the second polarity to the transfer roller 8. The voltage of the second polarity may be, for example, a transfer bias for promoting transfer of the toner image from the photosensitive drum 1 to the sheet P. The current detection circuit 203 is an example of a detection circuit that detects a charging current flowing between the charging roller 2 and the photosensitive drum 1. The CPU 13 is an example of a controller or a processor that controls the first power supply and the second power supply and obtains a surface potential (e.g., dark portion potential VD and bright portion potential VL) of the photosensitive drum 1 based on the charging current. In the current detection period (e.g., period i to iii), the CPU 13 operates the first power supply and the second power supply to apply the superimposed voltage generated by superimposing the voltage of the first polarity and the voltage of the second polarity to the transfer roller 8. Further, the CPU 13 is configured to determine the electric potential of the photosensitive drum 1 based on the charging current detected during the current detection. Thus, in the image forming apparatus 100 that generates the charging bias and the negative transfer bias at the same time, the surface potential (charging potential) of the photosensitive drum 1 is preferably obtained. The polarity of the superimposed voltage may be the first polarity or the second polarity.

During the current detection period, a voltage of a first polarity (e.g., a positive transfer bias) and a voltage of a second polarity (e.g., a charging bias Vb) are used. These are adjusted so that discharge occurs between the charging roller 2 and the photosensitive drum 1, and an electric discharge occurs does not occur between the transfer roller 8 and the photosensitive drum 1. That is, the voltage applied between the transfer roller 8 and the photosensitive drum 1 is adjusted to be less than the electric discharge start voltage. As a result, the influence of the transfer roller 8 on the surface potential of the photosensitive drum 1 is further reduced, and the charging current is accurately detected.

The period A is an example of the first period. The period C is an example of the second period. The absolute value of the voltage of the first polarity in the first period (e.g., −600 [V]) may be smaller than the absolute value of the voltage of the first polarity in the second period (e.g., −1200 [V]). As shown in FIGS. 6, 9, and 11, the voltage of the second polarity (e.g., positive transfer bias Vc, Vz) is not supplied to the transfer roller 8 in the first period (e.g., period A). In the second period (e.g., period C), the voltage of the second polarity is supplied to the transfer roller 8. The CPU 13 may determine the surface potential of the photosensitive drum 1 based on the first charging current (e.g., Ij) detected in the first period and the second charging current (e.g., Ib) detected in the second period. In the second period, the absolute value of the voltage of the first polarity is increased. Therefore, in this state, an electric discharge is likely to occur in the transfer roller 8. Therefore, by superimposing the voltage of the second polarity on the voltage of the first polarity, the electric discharge is less likely to occur in the transfer roller 8.

As shown in the mathematical expression Eq1, the CPU 13 divides the difference between the first charging current Ij and the second charging current Ib by the difference between the voltage of the first polarity supplied to the transfer roller 8 in the second period and the voltage of the first polarity supplied to the transfer roller 8 in the first period. As a result, the current change amount i per unit voltage is obtained. As shown in the mathematical expression Eq2, the CPU 13 may obtain the dark portion potential VD, which is the surface potential of the photosensitive drum 1, by dividing the second charging current Ib by the current change amount i. The mathematical expression Eq1, Eq2 is merely an example, and other mathematical expressions may be used to determine the dark portion potential VD.

The current detection period may include a first period (e.g., period A), a second period (e.g., period i), and a third period (e.g., period iii). The absolute value of the voltage of the first polarity (e.g., −600V) in the first period is smaller than the absolute value of the voltage of the first polarity (e.g., −1200V) in the second period. The absolute value of the voltage of the first polarity in the first period (e.g., −600V) is smaller than the absolute value of the voltage of the first polarity in the third period (e.g., −1200V). In the first period, the voltage of the second polarity is not supplied to the transfer roller 8. In the second period and the third period, the voltage of the second polarity (e.g., positive transfer bias) is supplied to the transfer roller 8. The first period and the second period are periods in which a surface portion of surface portions of the photosensitive drum 1 on the dark portion potential VD passes through the charging roller 2. The third period is a period in which a surface portion of surface portions of the photosensitive drum 1 that is on the bright portion potential VL passes through the charging roller 2. The CPU 13 may determine the surface potential of the photosensitive drum 1 based on the first charging current Ij detected in the first period, the second charging current Ib detected in the second period, and the third charging current If in the third period.

As shown in the mathematical expression Eq3, the CPU 13 may obtain the voltage by dividing the third charging current If by the current change amount i, and may obtain the bright portion potential VL by subtracting the voltage from the dark portion potential VD.

As indicated by the mathematical expression Eq2, the CPU 13 may obtain the dark portion potential VD by dividing the second charging current Ib by the current change amount i.

As mentioned in the second embodiment, the CPU 13 may adjust the voltage of the second polarity used in the current detection period in response to the resistance value of the transfer roller 8. As a result, the influence of the negative transfer bias in the current detection period is accurately reduced.

The environmental sensor 26 is an example of an environment detection circuit. As mentioned in the second embodiment, the CPU 13 may adjust the voltage of the second polarity (e.g., the positive transfer bias Vz) used during the current detection period, depending on the environmental conditions. As a result, the influence of the negative transfer bias in the current detection period is accurately reduced.

The current detection circuit 207 is an example of a current detection circuit that detects a transfer current flowing through the transfer roller 8. The CPU 13 may determine the target value Iz of the transfer current based on the environmental condition, and change an output voltage of the second power supply until the transfer current detected by the current detection circuit 207 reaches the target value. The voltage of the second polarity (e.g., positive transfer biased Vz) is determined based on the output voltage of the second power obtained at a time when the transfer current reaches the target value.

The memory 15 and the non-volatile memory 30, or a table, a mathematical function, or a program module stored therein function as a storage medium that holds a plurality of environmental conditions and a plurality of target values in association with each other in a one-to-one manner. The CPU 13 may be configured to acquire, from the storage medium, a target value corresponding to the environmental condition.

As illustrated in FIG. 9, the adjustment period (e.g., period Z) during which the voltage of the second polarity used in the current detection period is adjusted may be earlier than the current detection period (e.g., periods A to C).

As illustrated in FIG. 9, the period G is provided between the adjustment period and the current detection period, and is an example of a waiting period for returning the surface potential of the image bearing member to 0V.

As illustrated in FIG. 11, the adjustment period (e.g., period Z) may be provided between the first period (e.g., period A) and the second period (e.g., period C). As a result, the period G can be omitted, and the surface potential of the photosensitive drum 1 can be obtained in a shorter time.

As illustrated in FIG. 11, a standby period (e.g., period B) for returning the surface potential of the photosensitive drum 1 to 0V may be provided between the adjustment period (e.g., period Z) and the second period (e.g., period C).

As illustrated in FIG. 13, an adjustment period (e.g., period Z) in which the voltage of the second polarity (positive transfer bias Vz″) used in the second period (e.g., period C) is adjusted may be provided within the first period (e.g., period A) or may be provided in parallel with the first period.

As a result, the surface potential of the photosensitive drum 1 can be obtained in a shorter time.

As illustrated in FIG. 13, the CPU 13 obtains an output voltage (e.g., positive transfer bias Vz) when the transfer current reaches the target value Iz while changing the output voltage of the power supply circuit 206 in the adjustment period (e.g., period Z). Further, the CPU 13 may determine a voltage of the second polarity (e.g., a positive transfer bias Vz) based on the positive transfer bias Vz.

As shown in the mathematical expression Eq12, the CPU 13 obtains the difference between the voltage of the first polarity applied to the transfer roller 8 in the adjustment period and the first period (e.g., the charging bias Va) and the voltage of the first polarity applied to the transfer roller 8 in the second period (e.g., the charging bias Vb). The CPU 13 may determine a voltage of the second polarity (e.g., a positive transfer bias Vz) by adding the difference to an output voltage (e.g., a positive transfer bias Vz) when the transfer current reaches a target value.

As illustrated in FIG. 13, the light source 3 does not expose the photosensitive drum 1 in the period A and the period Z. The light source 3 exposes the photosensitive drum 1 in the period C. The CPU 13 may gradually increase the output voltage of the power supply circuit 206 until the transfer current reaches the target value Iz.

The CPU 13 may control the power supply circuit 202 to generate a voltage of the first polarity during the image forming period for forming the toner image, to supply the voltage of the first polarity to the charging member as a charging bias, and to supply the voltage of the first polarity to the transfer member as a cleaning bias. The CPU 13 may control the power supply circuit 206 to generate a voltage of the second polarity during the image forming period to supply the voltage of the second polarity to the transfer member as a transfer bias to promote transfer of the toner image from the image bearing member to the transfer material. The CPU 13 may stop the power supply circuit 206 while the power supply circuit 202 is in operation during the cleaning period for cleaning the transfer member. The CPU 13 may operate the power supply circuit 202 and the power supply circuit 206 during the current detection period in which the charging current is detected, thereby applying the superimposed voltage generated by superimposing the voltage of the first polarity and the voltage of the second polarity to the transfer member. The CPU 13 may determine the surface potential of the image bearing member based on the charging current detected during the current detection period.

### OTHER EMBODIMENTS

Embodiment(s) of the present invention can also be realized by a computer of a system or apparatus that reads out and executes computer executable instructions (e.g., one or more programs) recorded on a storage medium (which may also be referred to more fully as a ‘non-transitory computer-readable storage medium’) to perform the functions of one or more of the above-described embodiment(s) and/or that includes one or more circuits (e.g., application specific integrated circuit (ASIC)) for performing the functions of one or more of the above-described embodiment(s), and by a method performed by the computer of the system or apparatus by, for example, reading out and executing the computer executable instructions from the storage medium to perform the functions of one or more of the above-described embodiment(s) and/or controlling the one or more circuits to perform the functions of one or more of the above-described embodiment(s). The computer may comprise one or more processors (e.g., central processing unit (CPU), micro processing unit (MPU)) and may include a network of separate computers or separate processors to read out and execute the computer executable instructions. The computer executable instructions may be provided to the computer, for example, from a network or the storage medium. The storage medium may include, for example, one or more of a hard disk, a random-access memory (RAM), a read only memory (ROM), a storage of distributed computing systems, an optical disk (such as a compact disc (CD), digital versatile disc (DVD), or Blu-ray Disc (BD)™), a flash memory device, a memory card, and the like.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-011257, filed Jan. 29, 2024 which is hereby incorporated by reference herein in its entirety.

What is claimed is:

1. An image forming apparatus comprising:
an image bearing member;
a motor configured to rotationally drive the image bearing member;
a charging member configured to charge a surface of the image bearing member which is rotationally driven by the motor;
a light source configured to irradiate the surface of the image bearing member with light to form an electrostatic latent image;
a developing member configured to develop the electrostatic latent image using a toner charged to a first polarity to form a toner image;
a transfer member configured to transfer the toner image from the image bearing member to a transfer material;
a first power supply configured to generate a voltage of the first polarity, supply the voltage of the first polarity to the charging member as a charging bias, and supply the voltage of the first polarity to the transfer member;
a second power supply configured to generate a voltage of a second polarity opposite the first polarity and supply the voltage of the second polarity to the transfer member;
a detection circuit configured to detect a charging current flowing between the charging member and image bearing member; and
a controller configured to control the first power supply and the second power supply to determine a surface potential of the image bearing member based on the charging current,
wherein the controller is further configured to operate the first power supply and the second power supply in a current detection period in which the detection circuit detects the charging current, thereby applying a superimposed voltage generated by superimposing the voltage of the first polarity and the voltage of the second polarity to the transfer member, and to determine the surface potential of the image bearing member based on the charging current detected in the current detection period.

2. The image forming apparatus according to claim 1, wherein
the voltage of the first polarity and the voltage of the second polarity used in the current detection period are adjusted so that an electric discharge occurs between the charging member and the image bearing member, and an electric discharge does not occur between the transfer member and image bearing member.

3. The image forming apparatus according to claim 1, wherein
the current detection period includes a first period and a second period,
an absolute value of the voltage of the first polarity in the first period is smaller than an absolute value of the voltage of the first polarity in the second period,
in the first period, the voltage of the second polarity is not supplied to the transfer member,
in the second period, the voltage of the second polarity is supplied to the transfer member, and
the controller is further configured to determine the surface potential of the image bearing member based on a first charging current detected by the detection circuit in the first period and a second charging current detected by the detection circuit in the second period.

4. The image forming apparatus according to claim 3, wherein
the controller is further configured to determine a dark portion potential that is a surface potential of the image bearing member by dividing a difference between the first charging current and the second charging current by a difference between the voltage of the first polarity supplied to the transfer member in the second period and the voltage of the first polarity supplied to the transfer member in the first period to obtain a current change amount per unit voltage, and dividing the second charging current by the current change amount.

5. The image forming apparatus according to claim 1, wherein
the current detection period includes a first period, a second period, and a third period,
an absolute value of the voltage of the first polarity in the first period is smaller than an absolute value of the voltage of the first polarity in the second period, the absolute value of the voltage of the first polarity in the first period is smaller than an absolute value of the voltage of the first polarity in the third period,
in the first period, the voltage of the second polarity is not supplied to the transfer member,
the voltage of the second polarity in the second period and the third period is supplied to the transfer member,
the first period and the second period are periods during which a surface portion of surface portions of the image bearing member at a dark portion potential passes through the charging member,
the third period is a period during which the surface portion of the surface of the image bearing member at a bright portion potential passes through the charging member, and
the controller is further configured to determine the surface potential of the image bearing member based on a first charging current detected by the detection circuit in the first period, a second charging current detected by the detection circuit in the second period, and a third charging current detected by the detection circuit in the third period.

6. The image forming apparatus according to claim 5, wherein
the controller is further configured to determine the bright portion potential of the image bearing member by dividing a difference between the first charging current and the second charging current by a difference between the voltage of the first polarity supplied to the transfer member in the second period and the voltage of the first polarity supplied to the transfer member in the first period, to obtain a current change amount per unit voltage, dividing the third charging current by the current change amount to obtain a voltage, and subtracting the voltage from a dark portion potential of the image bearing member.

7. The image forming apparatus according to claim 6, wherein
the controller is further configured to determine the dark portion potential by dividing the second charging current by the current change amount.

8. The image forming apparatus according to claim 1, wherein
the controller is further configured to adjust the voltage of the second polarity used in the current detection period in accordance with a resistance value of the transfer member.

9. The image forming apparatus according to claim 1, further comprising
a sensor configured to detect an environmental condition of an environment in which the image forming apparatus is installed,
wherein the controller is further configured to adjust the voltage of the second polarity to be used during the current detection period according to the environmental condition.

10. The image forming apparatus according to claim 9, further comprising
a current detection circuit configured to detect a transfer current flowing through the transfer member,
wherein the controller is further configured to determine a target value of the transfer current based on the environmental condition, and change an output voltage of the second power supply until the transfer current detected by the current detection circuit reaches the target value, and the voltage of the second polarity is determined based on the output voltage of the second power obtained at a time when the transfer current reaches the target value.

11. The image forming apparatus according to claim 10, further comprising
a storage medium configured to hold a plurality of environmental conditions and a plurality of target values in association with each other in a one-to-one correspondence,
wherein the controller is further configured to obtain, from the storage medium, the target value corresponding to the environmental condition detected by the sensor.

12. The image forming apparatus according to claim 9, wherein
an adjustment period in which the voltage of the second polarity used in the current detection period is adjusted is located earlier than the current detection period.

13. The image forming apparatus according to claim 12, wherein
a waiting period for returning the surface potential of the image bearing member to 0V is provided between the adjustment period and the current detection period.

14. The image forming apparatus according to claim 1, wherein
the current detection period includes a first period and a second period,
an absolute value of the voltage of the first polarity in the first period is smaller than an absolute value of the voltage of the first polarity in the second period,
in the first period, the voltage of the second polarity is not supplied to the transfer member,
in the second period, the voltage of the second polarity is supplied to the transfer member, and
an adjustment period during which the voltage of the second polarity used in the second period is adjusted is provided between the first period and the second period.

15. The image forming apparatus according to claim 14, wherein
a waiting period for returning the surface potential of the image bearing member to 0V is provided between the adjustment period and the second period.

16. The image forming apparatus according to claim 1, wherein
the current detection period includes a first period and a second period,
an absolute value of the voltage of the first polarity in the first period is smaller than an absolute value of the voltage of the first polarity in the second period,
in the second period, the voltage of the second polarity is supplied to the transfer member, and
an adjustment period during which the voltage of the second polarity used in the second period is adjusted is provided within the first period or in parallel with the first period.

17. The image forming apparatus according to claim 16, further comprising:
a current detection circuit configured to detect a transfer current flowing through the transfer member; and
a sensor configured to detect environmental conditions,
wherein the controller is further configured to determine a target value of the transfer current based on the environmental condition, and
the controller is further configured to determine a voltage of the second polarity to be output in the second period based on the output voltage when the transfer current reaches the target value while changing an output voltage of the second power supply in the adjustment period.

18. The image forming apparatus according to claim 17, wherein
the controller is further configured to determine a voltage of the second polarity by adding a difference between the voltage of the first polarity applied to the transfer member in the adjustment period and the first period and the voltage of the first polarity applied to the transfer member in the second period to the output voltage when the transfer current reaches the target value.

19. The image forming apparatus according to claim 17, wherein
the light source is configured not to expose the image bearing member in the first period, and is configured to expose the image bearing member in the second period, and
the controller is further configured to control the second power supply to gradually increase the output voltage until the transfer current reaches the target value in the adjustment period.

20. The image forming apparatus according to claim 1, wherein
the first power supply is further configured to output a charging voltage that is the voltage of the first polarity to the charging member, and to output a transfer voltage that is the voltage of the first polarity to the transfer member and that changes in conjunction with the charging voltage.

21. The image forming apparatus according to claim 1, wherein
the polarity of the superimposed voltage is the first polarity.

22. The image forming apparatus according to claim 1, wherein
the voltage of the second polarity supplied to the transfer member from the second power supply is a transfer bias for promoting transfer of the toner image from image bearing member to the transfer material.

23. The image forming apparatus according to claim 1, wherein
the voltage of the first polarity supplied to the transfer member from the first power supply is a cleaning bias for re-transferring the toner adhered to the transfer member to image bearing member.

24. An image forming apparatus comprising:
an image bearing member;
a motor configured to rotationally drive the image bearing member;
a charging member configured to charge a surface of the image bearing member which is rotationally driven by the motor;
a light source configured to irradiate the surface of the image bearing member with light to form an electrostatic latent image;
a developing member configured to develop the electrostatic latent image using a toner charged to a first polarity to form a toner image;
a transfer member configured to transfer the toner image from the image bearing member to a transfer material;
a first power supply configured to generate a voltage of the first polarity and apply the voltage of the first polarity to both the charging member and the transfer member;
a second power supply configured to generate a voltage of a second polarity opposite to the first polarity and apply the voltage of the second polarity to the transfer member;
a detection circuit configured to detect a charging current flowing between the charging member and the image bearing member; and
a controller configured to control the first power supply and the second power supply to determine a surface potential of the image bearing member based on the charging current,
wherein the controller is further configured to control the first power supply to generate the voltage of the first polarity, to supply the voltage of the first polarity to the charging member as a charging bias, and to supply the voltage of the first polarity to the transfer member as a cleaning bias during an image forming period of forming the toner image,
the controller is further configured to control the second power supply to generate the voltage of the second polarity during the image forming period, and to supply the voltage of the second polarity to the transfer member as a transfer bias for promoting transfer of the toner image from the image bearing member to the transfer material,
the controller is further configured to, in a cleaning period for cleaning the transfer member, stop the second power supply while operating the first power supply, and
the controller is further configured to operate the first power supply and the second power supply in a current detection period in which the detection circuit detects the charging current, thereby applying a superimposed voltage generated by superimposing the voltage of the first polarity and the voltage of the second polarity to the transfer member, and to determine the surface potential of the image bearing member based on the charging current detected in the current detection period.
